(19) United States
(12) Patent Application Publication
(10) Pub. No.: US 2019/0043909 A1
(43) Pub. Date: Feb. 7, 2019

(54) ELECTRONIC IMAGE-CAPTURING DEVICE COMPRISING A LAYER FORMING OPTICAL LENSES

(71) Applicant: STMICROELECTRONICS (CROLLES 2) SAS, Crolles (FR)

(72) Inventor: Alain Ostrovsky, Grenoble (FR)

(21) Appl. No.: 16/053,440

(22) Filed: Aug. 2, 2018

(30) Foreign Application Priority Data
Aug. 4, 2017 (FR) 1757541

(51) Int. Cl. H01L 27/146

(52) U.S. Cl. CPC H01L 27/14627; G02B 3/0087; H01L 27/14636; H01L 27/14632

(57) ABSTRACT

An electronic image-capturing device includes a wafer having a face exposed to light and including pixel circuits able to deliver electrical signals in the form of pixels, respectively representative of the light reaching regions of the exposed face. The device includes a lens layer above the exposed face, that is configured to let the light pass. Sections of the lens layer, which respectively correspond to regions of the exposed face, are respectively provided with apertures able to modify the refractive index of the material of the lens layer. The apertures of each section are distributed so as to obtain, in each section, a refractive-index gradient such that the refractive index of the lens layer varies between a high refractive index in a local portion and a lower refractive index in a peripheral portion.

### BACKGROUND

### Technical Field

Embodiments of the present disclosure relate to the field of electronic devices able to capture images.

### Description of the Related Art

Electronic image-capturing devices, in particular CMOS devices, in which optical micro-lenses are formed from parallelepipedal pads that are obtained by etching a layer and that are made to flow under the effect of heat so as to confer a hemispherical shape thereon, are known.

### BRIEF SUMMARY

According to one embodiment, an electronic, image-capturing device is provided that comprises a wafer having a face exposed to light and including pixel circuits that, on capturing the light reaching said exposed face, are able to deliver electrical signals in the form of pixels, respectively representative of the light reaching regions of said exposed face.

The device furthermore comprises a lens layer above said exposed face, letting the light pass.

Sections of said lens layer, which respectively correspond to regions of said exposed face, are respectively provided with apertures able to modify the refractive index of the material of the lens layer.

The apertures of each section are distributed so as to obtain, in each section, a refractive-index gradient such that the refractive index of said lens layer varies between a high refractive index in a local portion and a lower refractive index in a peripheral portion.

Said lens layer may have a constant thickness.

Each section of said lens layer may be equivalent to a focusing optical lens.

The apertures of each section may be distributed so that the density of the apertures of each section increases from said local portion to said peripheral portion.

The apertures of each section may be distributed in said local portion and in annular portions that encircle this local portion, the distribution of the apertures being constant in each of said annular portions but the density of the apertures increasing from one portion to the next from the local portion to said peripheral portion.

The refractive-index gradient may result from variations in the shape and/or density of said apertures.

At least some of said apertures may pass right through the thickness of said lens layer.

At least some of said apertures may pass through some of the thickness of the lens layer.

The exposed face of said wafer may be flat and the exterior face of said lens layer may be flat.

Said lens layer may comprise sections in which the apertures are distributed differently so that the refractive-index gradients in these sections are different.

Said lens layer may comprise adjacent sections having different areas in which the apertures are distributed differently so that the refractive-index gradients in these sections are different.

The diameter of the apertures is preferably at least smaller than one quarter of the value of the illumination wavelength at which said pixel circuits are sensitive.

Said apertures of said lens layer may be at least partially filled with a least one material.

A process for fabricating an electronic image-capturing device is also provided, wherein a wafer has a face exposed to light and includes pixel circuits that, on capturing the light reaching said exposed face, are able to deliver electrical signals in the form of pixels, respectively representative of the light reaching regions of said exposed face.

The process comprises the following steps:

depositing a lens layer above said exposed face, made of a material letting the light pass; and

producing apertures in sections of said lens layer, which respectively correspond to regions of said exposed face, said apertures being able to modify the refractive index of the material of said lens layer.

### BRIEF DESCRIPTION OF THE SEVERAL VIEWS OF THE DRAWINGS

Electronic image-capturing devices will now be described by way of nonlimiting examples that are illustrated by the appended drawings, in which:

FIG. 1 shows a cross section of an electronic image-capturing device comprising a lens layer provided with apertures;

FIG. 2 shows a top view of the lens layer;

FIG. 3 shows a cross section of the lens layer provided with apertures according to one variant embodiment;

FIG. 4 shows a cross section of the lens layer provided with apertures according to another variant embodiment; and

FIG. 5 shows a cross section of the lens layer provided with apertures according to another variant embodiment.

### DETAILED DESCRIPTION

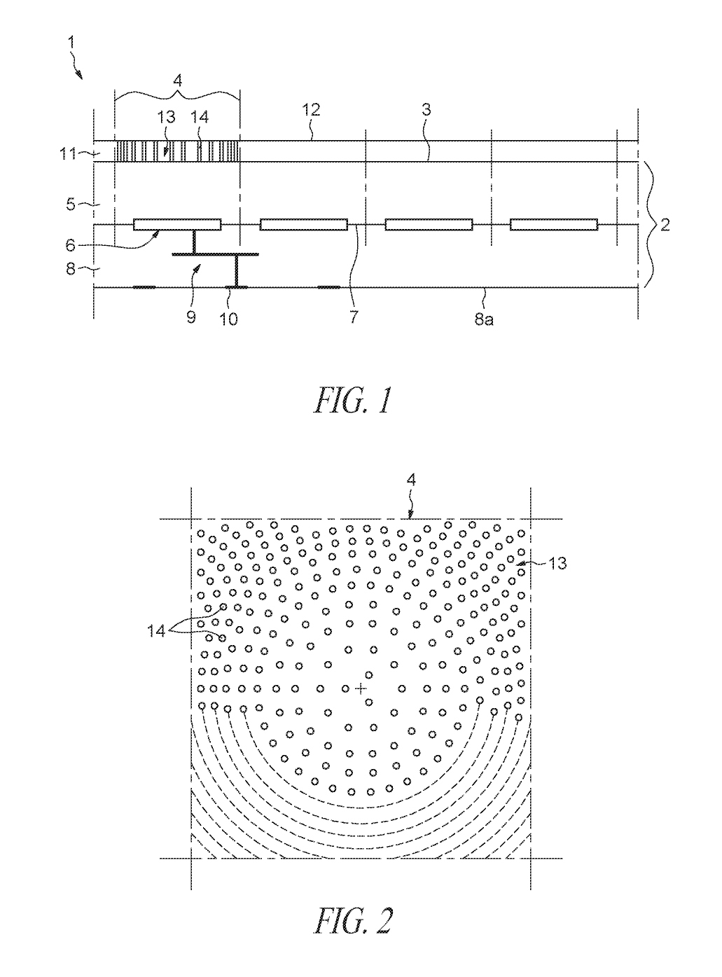

FIG. 1 illustrates an electronic, image-capturing device 1 that comprises, in its general form, a wafer 2 that has a face 3 exposed to light and that includes pixel circuits that, on capturing the light reaching the exposed face 3, are able to deliver electrical signals in the form of pixels, respectively representative of the light reaching regions 4 of the exposed face 3, for example square or rectangular regions, and able to define a digital matrix image.

For example, the wafer 2 comprises a substrate 5 including a semiconductor layer, for example made of silicon, and a dielectric layer 8. The substrate 5 includes the exposed face 3, is able to absorb the light, and defines a photosensitive zone. The dielectric layer 8 contacts a side 7 of the substrate 5 opposite the exposed face 3 and includes an integrated network 9 of electrical connections. Integrated in the substrate 5 and/or on the side 7 of the substrate 5 are electronic pixel circuits 6 configured to convert the light received at the respective regions 4 into electrical signals. The network 9 selectively connects the electronic pixel circuits 6 to rear exterior electrical-connection pads 10 produced on an exterior face 8a of the dielectric layer 8. The integrated network 9 may include a plurality of metal levels connected by vias.

In one embodiment, the electronic pixel circuits 6 comprise transistors and charge-storage capacitors and deliver, to the rear pads 10, signals in the form of pixels, respectively representative of the light reaching the regions 4 of the exposed face 3 of the substrate 5. It will be appreciated that the pixel circuits 6 may implemented by various imaging circuits, such as complementary metal oxide semiconductor (CMOS) pixel circuits, charge coupled device (CCD) pixel circuits, and single photon avalanche diode (SPAD) pixel circuits.

The wafer 2 could have a structure other than that described above.

The electronic device 1 comprises a lens layer 11 above said exposed face 3 of the wafer 2, made of a material letting the light pass. The lens layer 11 has an exterior face 12 exposed to the light.

In the example shown, the exposed face 3 of the wafer 2 is flat, the exposed face 12 of the lens layer 11 is flat, and the lens layer 11 has a constant thickness.

Sections 13 of the lens layer 11, which respectively correspond to the regions 4 of the exposed face 3 of the wafer 2, are respectively provided with a plurality of apertures 14 able to modify the refractive index of the lens layer 11.

The apertures 14 of each section 13 are distributed so as to obtain a refractive-index gradient such that the refractive index of the lens layer 11 varies between a high refractive index in a non-peripheral local portion, for example a portion that is central or offset with respect to the center, and a lower refractive index in a peripheral portion, in order to produce a light-focusing effect.

Thus, the regions 4 of the lens layer 11, which have parallel opposite faces and which are provided with apertures 14, may be engineered to produce focusing optical-lens effects that are equivalent to optical, spherical for example, lenses—namely one lens per pixel.

The expression “distribution of the apertures” is understood to mean relative variations in the topography of the apertures and/or in their size and/or in the shape of the walls of the apertures.

According to one example of a distribution, which example is illustrated in FIGS. 2 and 3, the apertures 14 of the sections 13 pass through the lens layer 11, i.e., they extend completely through the thickness of the lens layer 11.

In the embodiment of FIGS. 2 and 3, the apertures 14 are cylindrical and of the same diameter, are placed on concentric circles and at equal distances from one another on each circle, and are provided in the corners of the sections 13.

In FIGS. 2-3, the density of the apertures 14 increases between the central portion and the peripheral portion of the sections 13, continuously or in steps between concentric annular portions. The term “density” is understood to mean the value of the cross-sectional area of an aperture or of the cumulative cross-sectional area of the apertures per unit area of the section 13.

Preferably, the diameter of the apertures 14 is at least smaller than one quarter of the value of the illumination wavelength at which the pixel circuits for capturing light are sensitive. Advantageously, the diameter of the apertures 14 is approximately smaller than one tenth of the value of the illumination wavelength at which the pixel circuits for capturing light are sensitive.

According to one variant distribution illustrated in FIG. 4, the apertures 14 are produced from the front face 12 and are blind, i.e., they extend through some of the thickness of the lens layer 11 without extending completely through. The apertures 14 have the same depth in the embodiment of FIG. 4.

The unapertured portion 13a located on that side of the lens layer 11 which faces the substrate 5 then forms an antireflection layer.

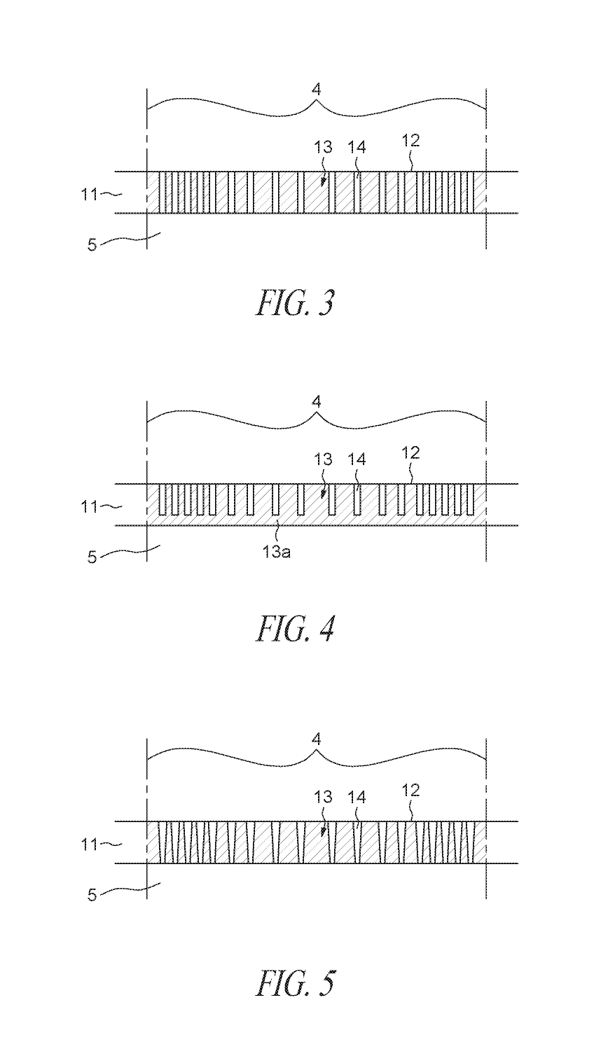

According to another variant distribution illustrated in FIG. 5, the apertures 14 have walls in the shape of a conical frustum, the largest diameter of which is on the side of the face 12.

A gradient is thus achieved in the variation of the refractive index in the thickness direction of the lens layer 11.

As above, the apertures 14 may be produced right through or through some of the thickness of the layer 11.

The distributions of the apertures 14 described above may be combined. Other distributions of the apertures 14 may be envisaged, for example apertures with diameters that are terraced in the thickness direction of the lens layer 11 or apertures of square or rectangular cross sections.

In one particular arrangement (not shown), adjacent sections 13 may have different distributions of the apertures 14, able to produce different focusing effects, corresponding to different spherical lenses.

In another particular arrangement (not shown), adjacent regions 4 may have different, for example square or rectangular, areas, in particular with a view to capturing different wavelengths, or may be located facing photodiodes of different areas. In this case, the corresponding sections 13 may have different distributions of the apertures 14, able to produce different focusing effects, corresponding to different spherical lenses.

In one embodiment, the electronic image-capturing device 1 is fabricated in the following way. The wafer 2 having been provided, at least one lens layer 11 made of a material letting the light pass is deposited. Next, the apertures 14 are produced.

The lens layer 11 may be made of silicon nitride, of silicon oxide, or of polysilicon, obtained by chemical vapor deposition (CVD), or may be made of a polymer resist obtained by spreading.

The apertures 14 may be produced by chemical attack or by etching.

The thickness of the lens layer 11 may be approximately equal to one micron.

The diameter of the apertures 14 may be at least smaller than one quarter, preferably smaller than approximately one tenth, of the value of the illumination wavelength at which said pixel circuits for capturing light are sensitive. For example, for a wavelength equal to 0.8 microns, the diameter may be comprised between a few nanometers and 0.2 microns. The density of the apertures 14 may range from zero percent in the central portion to a maximum density in the peripheral portion.

According to one variant applicable to all the above embodiments, the apertures 14 may be filled with a second material that is different from the first material forming the lens layer 11 and that has an optical refractive index that is sufficiently different with respect to the first material, so as to close the apertures and to achieve a flat exterior face 12 so as to allow one or more additional layers, for example optical filters, to be deposited on top of the face 12 of the structure 1. By way of example, if the material of the lens layer 11 is silicon nitride, the filler material may be silicon oxide.

According to yet another variant, the apertures 14 may be only partially filled, in their upper section, so as to obstruct them, for example with a nonconformal air-gap CVD deposition, in order to form “air-filled” apertures (that in fact are filled with a residual gas or vacuum). The advantage of this is to allow the exterior surface 12 to be planarized while preserving air (or vacuum) in the interior of the apertures 14, i.e., while preserving a maximum optical index difference between the material of the lens layer 11 and the apertures 14 formed in the latter.

Embodiments of the lens layer 11 provided with apertures 14, and thus including a network of planar micro-lenses, have been described, in which the layer is located on the face 3 of a backside-illuminated (BSI) electronic image-capturing device. According to a variant embodiment (not illustrated in the figures), it is possible to form the lens layer 11 provided with apertures 14 on a front-side-illuminated (FSI) electronic image-capturing device, i.e., by forming the lens layer 11 and the apertures 14 above the face 8a of the dielectric layer 8, the face 8a forming the face exposed to light that then reaches the face 7 of the substrate 5. The positions of the network 9 and of the electrical contacts 10 are modified accordingly.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic image-capturing device, comprising
a wafer having a face exposed to light and including pixel circuits configured to capture light reaching respective regions of said face and deliver electrical signals as pixels, respectively representative of the light reaching the regions of said face, respectively;
a lens layer on said face, said lens layer including sections that respectively correspond to the regions of said face, the sections being respectively provided with apertures able to modify a refractive index of the lens layer, the apertures of each section being distributed so as to obtain, in each section, a refractive-index gradient such that the section has a refractive index that varies between a high refractive index in a local portion and a lower refractive index in a peripheral portion.

2. The device according to claim 1, wherein said lens layer has a constant thickness.

3. The device according to claim 1, wherein each aperture has a conical frustum shape.

4. The device according to claim 1, wherein the apertures of each section have a density that increases from said local portion to said peripheral portion.

5. The device according to claim 1, wherein the apertures of each section have a distribution in said local portion and in annular portions that encircle the local portion, the distribution of the apertures being constant in each of said annular portions and the apertures have a density increasing from the local portion to each successive annular portion until said peripheral portion.

6. The device according to claim 1, wherein the refractive-index gradient results from variations in shape and/or density of said apertures.

7. The device according to claim 1, wherein at least some of said apertures pass completely through a thickness of said lens layer.

8. The device according to claim 1, wherein at least some of said apertures pass through some of a thickness of the lens layer without passing completely through the thickness of the lens layer.

9. The device according to claim 1, wherein the face of said wafer is flat and an exterior face of the lens layer is flat.

10. The device according to claim 1, wherein the apertures of first and second sections of the sections of the lens layer are distributed differently such that the refractive-index gradients in the first and second sections are different.

11. The device according to claim 1, wherein adjacent sections of the sections of the lens layer have different areas in which the apertures are distributed differently such that the refractive-index gradients in the adjacent sections are different.

12. The device according to claim 1, wherein the apertures have respective diameters that are at least smaller than one quarter of an illumination wavelength at which said pixel circuits are sensitive.

13. The device according to claim 1, wherein said apertures of said lens layer are at least partially filled with at least one material.

14. A process, comprising:
fabricating an electronic image-capturing device, the fabricating including:
forming pixel circuits in a wafer that has a face exposed to light, the pixel circuits being configured to convert the light reaching said exposed face into electrical signals as pixels, respectively representative of the light reaching regions of said exposed face;
depositing a lens layer on said exposed face, made of a material letting the light pass; and
producing apertures in sections of said lens layer, which respectively correspond to regions of said exposed face, said apertures modifying a refractive index of the lens layer.

15. The method according to claim 14, wherein producing the apertures includes distributing the apertures of each section such that the apertures of each section have a density that increases from a non-peripheral portion to a peripheral portion.

16. The device according to claim 14, wherein producing the apertures includes distributing the apertures of each section such that the apertures of each section have a distribution in a central portion and in annular portions that encircle the central portion, the distribution of the apertures being constant in each of said annular portions and the apertures have a density increasing from the central portion to each successive annular portion until a peripheral portion.

17. The device according to claim 14, wherein producing the apertures includes distributing the apertures of each section such that each section has a refractive-index gradient in that the section has a refractive index that varies between a high refractive index in a non-peripheral portion and a lower refractive index in a peripheral portion.

18. An electronic image-capturing device, comprising
a wafer including pixel circuits configured to capture light reaching respective regions of a face of the wafer and deliver electrical signals as pixels, respectively representative of the light reaching the regions of said face, respectively;
a planar lens layer on said face, said planar lens layer including sections that respectively correspond to the regions of said exposed face, each section having a refractive-index gradient such that the section has a refractive index that varies between a high refractive index in a non-peripheral portion and a lower refractive index in a peripheral portion.

19. The device according to claim 18, wherein each section includes a plurality of apertures that are arranged to provide the refractive-index gradient.

20. The device according to claim 19, wherein said apertures of said planar lens layer are at least partially filled with at least one material.
